(19) United States
(12) Patent Application Publication
(10) Pub. No.: US 2025/0316305 A1
(43) Pub. Date: Oct. 9, 2025

(54) MEMORY DEVICE, SENSE AMPLIFIER AND MEMORY CIRCUIT

(71) Applicant: Samsung Electronics Co., Ltd., Suwon-si (KR)

(72) Inventor: Yesin Ryu, Suwon-si (KR)

(21) Appl. No.: 19/088,061

(22) Filed: Mar. 24, 2025

(30) Foreign Application Priority Data
Apr. 3, 2024 (KR) 10-2024-0045596
Jul. 18, 2024 (KR) 10-2024-0095299

(51) Int. Cl. G11C 11/4091; G11C 11/4074; G11C 11/4094

(52) U.S. Cl. CPC G11C 11/4091; G11C 11/4074; G11C 11/4094

(57) ABSTRACT

A memory device includes a plurality of memory cells and a plurality of sense amplifiers electrically connected to the one or more of plurality of memory cells and each of the plurality of sense amplifiers are configured to sense and amplify a bitline signal of a bitline to produce an amplified bitline signal. At least one of the plurality of sense amplifiers may be configured to perform operations which includes generating a matching signal, indicating whether a first bit value corresponding to the amplified bitline signal and a second bit value corresponding to a first input signal match, based on first and second input signals that are input through first and second input lines, respectively, where the first input signal and the second input signal are complementary to one another; and controlling a voltage on a match line, based on the matching signal.

### CROSS-REFERENCE TO RELATED APPLICATION(S)

This U.S. non-provisional application claims priority under 35 USC § 119 to Korean Patent Application No. 10-2024-0045596, filed on Apr. 3, 2024, and Korean Patent Application No. 10-2024-0095299, filed on Jul. 18, 2024, in the Korean Intellectual Property Office, the disclosures of which are herein incorporated by reference in their entirety.

### FIELD

The present inventive concepts relate to a memory device, a sense amplifier, and a memory circuit.

### BACKGROUND

A typical processing unit, such as a central processing unit (CPU) or a graphics processing unit (GPU), fetches and processes instructions or data stored in a high-capacity external memory. Since processing speed of most high-capacity external memories is significantly lower than that of a processing unit, a cache memory system is used to improve operational speed.

In a cache memory system, operations are performed to determine whether data requested by a processing unit is present within a cache memory.

### SUMMARY

Example embodiments provide a memory device, a sense amplifier, and a memory circuit, capable of determining whether data stored in a memory cell matches external input data.

According to example embodiments, a memory device includes a plurality of memory cells, and a plurality of sense amplifiers electrically connected to one or more of the plurality of memory cells. Each of the plurality of sense amplifiers are configured to sense and amplify a bitline signal of a bitline to produce an amplified bitline signal. At least one of the plurality of sense amplifiers may be configured to perform operations including generating a matching signal, indicating whether a first bit value corresponding to the amplified bitline signal and a second bit value corresponding to a first input signal match, based on first and second input signals that are input through first and second input lines, respectively, where the first input signal and the second input signal are complementary to one another, and controlling a voltage on a match line, based on the matching signal.

The at least one sense of the plurality of sense amplifiers may include a sensing circuit configured to detect a voltage change of the bitline signal and amplify both the bitline signal and a complementary bitline signal of a complementary bitline based on the voltage change that was detected, during a row activation operation, a precharge circuit configured to precharge the bitline and the complementary bitline to a first precharge voltage during a precharge operation and generate the matching signal based on the first and second input signals during a comparison operation, and a match circuit configured to control the voltage on the match line according to the matching signal.

The precharge circuit may include a first transistor electrically connected between the bitline and the complementary bitline and configured to be controlled based on a first control signal, a second transistor electrically connected between the bitline and a match node and configured to be controlled by the second input signal, a third transistor electrically connected between the match node and the complementary bitline and configured to be controlled by the first input signal, and a fourth transistor electrically connected between a reference line and the match node and configured to be controlled by a second control signal. The match circuit may include a pull-down transistor electrically connected to the match line and configured to be controlled by the matching signal at the match node.

A first voltage of each of the first control signal, the first input signal, the second input signal, and the second control signal may turn on a corresponding transistor during the precharge operation. The first precharge voltage may be applied to the reference line during the precharge operation, and may be transferred to the bitline and to the complementary bitline by the fourth transistor, the second transistor, and the third transistor.

A first voltage of each of the first control signal, the first input signal, and the second input signal may turn off a corresponding transistor during the row activation operation. A second voltage of the second control signal may turn on the fourth transistor during the row activation operation. When a ground voltage is applied to the reference line during the row activation operation, the ground voltage is also applied to the match node.

The comparison operation may include a first operation configured to precharge the match line to a second precharge voltage and a second operation configured to generate the matching signal and configured to control the voltage on the match line based on the matching signal, and the match line is precharged to the second precharge voltage.

A first voltage of each of the first control signal and the second control signal may turn off a corresponding transistor during the second operation, and the first input signal and the second input signal may have first and second voltages during the second operation, where the first and second voltages are complementary to one another.

The pull-down transistor may be configured to perform operations including controlling the voltage on the match line when the matching signal of a first voltage is generated, where the first voltage is generated when the first bit value and the second bit value match, and controlling the voltage on the match line when the matching signal of a second voltage is generated, where the second voltage is generated when the first bit value and the second bit value do not match.

The matching signal may have the second voltage when the first bit value is 1 and the second bit value is 0, the matching signal may have the second voltage when the first bit value is 0 and the second bit value is 1, the matching signal may have the first voltage when the first bit value is 0 and the second bit value is 0, and the matching signal may have the first voltage when the first bit value is 1 and the second bit value is 1.

The precharge circuit may further include a fifth transistor configured to be controlled by a third control signal and electrically connected between a precharge voltage line to which the first precharge voltage is applied, and the bitline.

The memory device may include a column selection circuit configured to transfer the amplified bitline signal and the complementary bitline signal that was amplified to a global data line and a complementary global data line, respectively. The column selection circuit may include a sixth transistor, electrically connected between the bitline and the global data line. The sixth transistor is configured to be controlled by a column select signal, and a seventh transistor electrically connected between the complementary bitline and the complementary global data line. The seventh transistor is configured to be controlled by the column select signal.

A first voltage of the column select signal may turn on the sixth transistor and the seventh transistor during a normal read operation.

Each of the plurality of memory cells may include one of a dynamic random access memory (DRAM) cell, a static random access memory (SRAM) cell, or a magnetic random access memory (MRAM) cell.

The plurality of memory cells may include a plurality of first memory cells electrically connected to a same wordline and each of the plurality of first memory cells is configured to store a tag bit of a plurality of tag bits from tag data, where the tag data includes an identification value of a cache block. The at least one of the plurality of sense amplifiers may include a plurality of first sense amplifiers, respectively corresponding to the plurality of first memory cells. First input signals that are input to the plurality of first sense amplifiers may correspond to the plurality of tag bits from the tag data of a search-requested cache block, respectively, and the first input signals include the first input signal.

The first bit values include a first tag bit stored in a respective first memory cell of the plurality of first memory cells, and the second bit value includes a second tag bit corresponding to a respective first input signal of the first input signals. Each of the plurality of first sense amplifiers may be configured to generate the matching signal of a first voltage when the first bit value and the second bit value match, and may be configured to generate the matching signal of a second voltage when the first bit value and the second bit value do not match.

Each of the plurality of first sense amplifiers may include a pull-down transistor electrically connected to the match line and configured to control the voltage on the match line based on the matching signal. The match line may be configured to be precharged to a second precharge voltage The pull-down transistor is configured to maintain the second precharge voltage on the match line when respective matching signals of the plurality of first sense amplifiers have the first voltage, and may be configured to transfer a ground voltage to the match line when at least one of the respective matching signals of the plurality of first sense amplifiers has the second voltage.

The memory device may further include a way selection circuit configured to output a way selection signal for selecting the cache block corresponding to the tag data stored in the plurality of first memory cells, based on the match line being maintained at the second precharge voltage.

The plurality of memory cells may include a plurality of second memory cells configured to store data of the cache block corresponding to the tag data stored in the plurality of first memory cells, and the data stored in the plurality of second memory cells may be output to an exterior of the memory device based on a way select signal of the way selection circuit.

According to example embodiments, a sense amplifier electrically connected to a bitline and a complementary bitline include a sensing circuit configured to detect a voltage change of a bitline signal and amplify the voltage change that was detected based on the bitline signal and a complementary bitline signal to produce an amplified bitline signal, a precharge circuit configured to precharge the bitline and the complementary bitline to a precharge voltage, and a pull-down transistor electrically connected to a match line. The precharge circuit may be configured to generate a matching signal indicating whether a first bit value corresponding to the amplified bitline signal matches a second bit value corresponding to a first input signal, based on the first input signal and a second input signal that are input through first and second input lines, respectively, where the first input signal and the second input signal are complementary to one another, and the pull-down transistor may be configured to control a voltage on the match line, based on the matching signal.

According to example embodiments, a memory circuit electrically connected to a bitline and a complementary bitline where the memory circuit is configured to perform a precharge operation on the bitline and the complementary bitline, and includes a first transistor electrically connected between the bitline and the complementary bitline, a second transistor electrically connected between the bitline and a match node and configured to be controlled by a second input signal, a third transistor electrically connected between the match node and the complementary bitline and configured to be controlled by a first input signal, and a fourth transistor configured to transfer a precharge voltage to the match node. The bitline and the complementary bitline may be configured to be precharged to the precharge voltage while the first transistor, the second transistor, the third transistor, and the fourth transistor are turned on. The match node may have a first voltage indicating whether a first bit value corresponding to a bitline signal matches a second bit value corresponding to the first input signal, in response to the first transistor and the fourth transistor being turned off and the first and second input signals being input through the second transistor and the third transistor, respectively, where the first and second input signals are complementary to one another.

### BRIEF DESCRIPTION OF THE DRAWINGS

Embodiments will be more clearly understood from the following detailed description taken in conjunction with the accompanying drawings in which:

FIG. 1 is a block diagram of a memory system according to example embodiments;

FIG. 2 is a diagram illustrating a bank structure of a memory device according to example embodiments;

FIG. 3 is a block diagram of a memory device according to example embodiments;

FIG. 4 is a block diagram of a memory device illustrating a memory circuit according to example embodiments of FIG. 3;

FIG. 5 is a circuit diagram of a memory device according to example embodiments;

FIG. 6 is a timing diagram illustrating the operation of a memory circuit according to example embodiments;

FIG. 7A is a circuit diagram illustrating a precharge operation of the memory circuit of FIG. 5;

FIG. 7B is a circuit diagram illustrating a comparison operation of the memory circuit of FIG. 5;

FIG. 8 is a circuit diagram illustrating a memory circuit according to example embodiments;

FIG. 9A is a circuit diagram of a memory device according to example embodiments;

FIG. 9B is a circuit diagram of a memory device according to example embodiments; and

FIG. 10 is a diagram illustrating the operation of a memory device according to example embodiments.

### DETAILED DESCRIPTION OF EMBODIMENTS

Hereinafter, example embodiments will be described in detail with reference to the accompanying drawings.

The terms “first,” “second,” and/or the like as used herein may describe various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to physical and/or electrical connection.

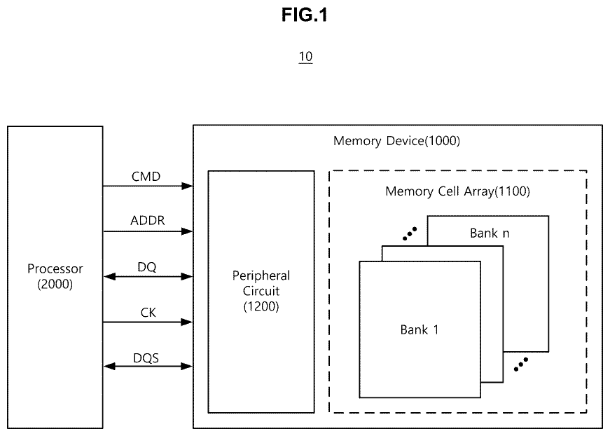

FIG. 1 is a block diagram of a memory system according to example embodiments. Referring to FIG. 1, a memory system 10 may include a processor 2000 and a memory device 1000.

The processor 2000 may control the memory device 1000. The processor 2000 may include one or more cores. The processor 2000 may include at least one of a central processing unit (CPU), a general-purpose graphics processing unit (GPU), an application processor (AP), a communication processor (CP), and/or a tensor processing unit (TPU).

The processor 2000 may be included in a host and may control the memory device 1000 in response to requests from various applications such as a server application, a personal computer (PC) application, and/or a mobile application.

The processor 2000 may transmit a clock signal CK, a command CMD, and/or an address ADDR to the memory device 1000 to control the memory device 1000. In addition, the processor 2000 may transmit a data signal DQ to the memory device 1000 and/or receive a data signal DQ from the memory device 1000. When reading the data signal DQ from the memory device 1000, the processor 2000 may receive a data strobe signal DQS from the memory device 1000. When writing the data signal DQ in the memory device 1000, the processor 2000 may transmit the data strobe signal DQS to the memory device 1000.

The memory device 1000 may receive data from the processor 2000 and store the received data. The memory device 1000 may read the stored data in response to a request from the processor 2000 and transmit the read data to the processor 2000.

In example embodiments, the memory device 1000 may be a memory device including volatile memory cells. For example, the memory device 1000 may be one of various DRAM devices such as a double data rate synchronous dynamic random access memory (DDR SDRAM) device, a DDR2 SDRAM device, a DDR3 SDRAM device, a DDR4 SDRAM device, a DDR5 SDRAM device, a DDR6 SDRAM device, a low power double data rate (LPDDR) SDRAM device, an LPDDR2 SDRAM device, an LPDDR3 SDRAM device, an LPDDR4 SDRAM device, an LPDDR4X SDRAM device, an LPDDR5 SDRAM device, a graphics double data rate synchronous graphics random access memory (GDDR SGRAM) device, a GDDR2 SGRAM device, a GDDR3 SGRAM device, a GDDR4 SGRAM device, a GDDR5 SGRAM device, or a GDDR6 SGRAM device.

In example embodiments, the memory device 1000 may be a stacked memory device in which DRAM dies are stacked, such as a high bandwidth memory (HBM) device, an HBM2 device, or an HBM3 device.

In example embodiments, the memory device 1000 may be a memory module such as a dual in-line memory module (DIMM). For example, the memory module 100A may be a registered DIMM (RDIMM), a load reduced DIMM (LRDIMM0, an unbuffered DIMM (UDIMM), a fully buffered DIMM (FB-DIMM), or a small outline DIMM (SO-DIMM). The present inventive concepts, however, are not limited thereto, and the memory device 1000 may be another memory module such as, for example, a single in-line memory module (SIMM).

In example embodiments, the memory device 1000 may be an SRAM device, a NAND flash memory device, a NOR flash memory device, an RRAM device, an FRAM device, a PRAM device, a TRAM device, or an MRAM device.

The memory device 1000 may include a memory cell array 1100 and a peripheral circuit 1200.

The memory cell array 1100 may include a plurality of memory cells formed at intersections of wordlines and bitlines. The memory cell array 1100 may include a plurality of banks Bank 1 to Bank n, and each respective bank may include memory cells configured to store data. For ease of description, example embodiments will be provided in which each bank includes DRAM cells. The present inventive concepts, however, are not limited thereto, and each of the plurality of banks, Bank 1 to Bank n, may be configured to include memory cells of a type other than DRAM cells. In addition, each of the plurality of banks, Bank 1 to Bank n, may be configured to include memory cells of the same type or a different type. In other words, the plurality of banks in the memory cell array 1100 may include a single type of memory cell (e.g. DRAM, SRAM, or MRAM) or each bank of the plurality of banks in the memory cell array 1100 may include the same type of memory cells or a different type of memory cells as the type comprising another bank. For example, the memory cells of Bank 1 may include SRAM cells, the memory cells of Bank 2 may include DRAM cells, the memory cells of Bank n-1 may include DRAM cells, and the memory cells of Bank n may comprise MRAM cells.

Memory cells in each bank may be subdivided into memory array tiles (MATs) to reduce the capacitance of local wordlines and local bitlines with shorter wires. Therefore, according to example embodiments, each of the banks Bank 1 to Bank n may include a plurality of MATs.

The peripheral circuit 1200 may include various circuits to drive the memory cell array 1100. For example, the peripheral circuit 1200 may include a row decoder and a column decoder corresponding to each of the plurality of banks Bank 1 to Bank n. In addition, the peripheral circuit 1200 may include a sub-wordline driver group and a bitline sense amplifier group corresponding to each of the plurality of MATs.

The peripheral circuit 1200 may include a command decoder, an address register, a delayed locked loop (DLL), an error correction code (ECC) engine, a data input/output buffer, and a power circuit. In addition, the peripheral circuit 1200 may include drivers to provide various control signals and input signals to be described later.

According to example embodiments, the memory device 1000 may be a content addressable memory (CAM) device. The memory cell array 1100 may store a tag, an identification value of a cache block. Then, when a search-requested tag is input, the memory device 1000 may compare the input tag with a tag stored in the memory cell array 1100. When a matching tag is identified as a result of the comparison operation, the memory device 1000 may output an address for accessing the cache block that corresponds to the input tag based on the address (e.g., a way address) corresponding to memory cells storing the matching tag.

According to example embodiments, the memory device 1000 may be a cache memory device including a CAM device. The memory cell array 1100 may store a tag of a cache block and data of the cache block. According to example embodiments, the tag and data may be stored in different MATs within a bank of the memory cell array 1100. For example, the tag may be stored in a first MAT, and the data corresponding to the stored tag may be stored in a second MAT. Then, when a search-requested tag is input, the memory device 1000 may compare the input tag with the tag stored in the memory cell array 1100. When a matching tag is present as a result of the comparison operation, the memory device 1000 may output data of the cache block that corresponds to the input tag based on an address (e.g., a way address) corresponding to memory cells storing the matching tag.

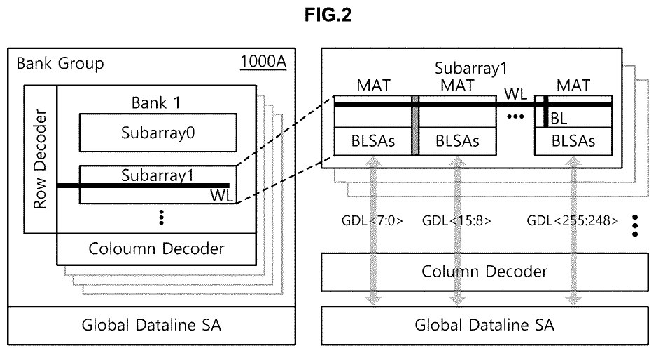

FIG. 2 is a diagram illustrating a bank structure of a memory device according to example embodiments. A memory device 1000A of FIG. 2 may be an example embodiment of the memory device 1000 of FIG. 1, but example embodiments are not limited thereto. Referring to FIG. 2, the memory device 1100A may include a bank group and a global dataline sense amplifier.

The bank group may include a plurality of banks. Each of the plurality of banks may be controlled by a row decoder and a column decoder corresponding to the bank. For example, a row decoder corresponding to Bank 1 may activate a wordline corresponding to a row address, among wordlines included in Bank 1. A column decoder corresponding to Bank 1 may select bitlines corresponding to a column address, among bitlines included in Bank 1. Signals of bitlines selected by the column decoder may be transmitted to a global dataline sense amplifier through global data lines, and may be amplified by the global dataline sense amplifier and then output to a data input/output pad.

According to example embodiments, each of the plurality of banks may include at least one subarray. The subarray may be a group of MATs that may be accessed together. For example, MATs belonging to a single subarray may be electrically connected to the same wordlines, but example embodiments are not limited thereto.

According to example embodiments, bitline sense amplifiers BLSAs corresponding to at least one MAT of a plurality of MATs belonging to a single subarray, may compare data corresponding to a bitline signal with external input data and generate a matching signal.

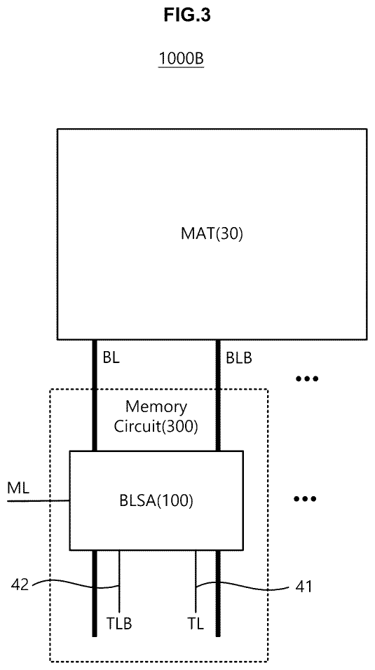

Hereinafter, various example embodiments of a sense amplifier generating a matching signal will be described with reference to FIGS. 3 to 8.

FIG. 3 is a block diagram of a memory device according to example embodiments. A memory device 1000B of FIG. 3 may be an example embodiment of the memory devices 1000 and 1000A of FIGS. 1 and 2, but example embodiments are not limited thereto.

Referring to FIG. 3, the memory device 1000B may include a MAT 30 and a memory circuit 300. The MAT 30 may be a component of the memory cell array 1100 as described above in FIGS. 1 and 2. The MAT 30 may include a plurality of memory cells formed at intersections of wordlines and bitlines.

According to example embodiments, the MAT 30 may be controlled by a corresponding sub-wordline driver group and a corresponding bitline sense amplifier group. The corresponding sub-wordline driver group may include a plurality of sub-wordline drivers driving wordlines included in the MAT 30. The corresponding bitline sense amplifier group may include a plurality of bitline sense amplifiers driving the bitlines included in the MAT 30.

The memory circuit 300 may be a column circuit electrically connected to a bitline BL and a complementary bitline BLB of the MAT 30. The memory circuit 300 may include a bitline sense amplifier 100. The bitline sense amplifier 100 may be a single bitline sense amplifier among a plurality of bitline sense amplifiers belonging to a bitline sense amplifier group controlling the MAT 30.

The bitline sense amplifier 100 may sense and amplify a bitline signal of the bitline BL. For example, the bitline sense amplifier 100 may detect a voltage change on a bitline, and amplify a bitline signal based on the voltage change that was detected.

The bitline sense amplifier 100 may receive a first input signal TL through a first input line 41 and a second input signal TLB through a second input line 42. The first input line 41 and the second input line 42 may be independent of the bitline and the complementary bitline.

The bitline sense amplifier 100 may generate a matching signal indicating whether a first bit value corresponding to the amplified bitline signal matches a second bit value corresponding to a first input signal TL, in response to first and second input signals TL and TLB being respectively input through the first and second input lines 41 and 42, where the first and second input signals TL and TLB are complementary to one another.

For example, when the first bit value and the second bit value match, the bitline sense amplifier 100 may generate a matching signal of a first level or a first voltage. When the first bit value and the second bit value do not match, the bitline sense amplifier 100 may generate a matching signal of a second level or a second voltage. For example, the bitline sense amplifier 100 may perform an XOR operation on the first bit value and the second bit value.

The bitline sense amplifier 100 may control whether a voltage on a match line ML is pulled down, based on the matching signal. For example, the bitline sense amplifier 100 may maintain the voltage on the match line ML based on the matching signal of the first level or a first voltage. Also, the bitline sense amplifier 100 may be configured to pull down the voltage on the match line ML based on the matching signal of the second level or the second voltage.

According to the above-described example embodiments, the bitline sense amplifier 100 may generate a matching signal indicating whether data stored in the memory cell (e.g., the first bit value) matches external input data (e.g., the second bit value), and may control the voltage on the match line ML based on the generated matching signal.

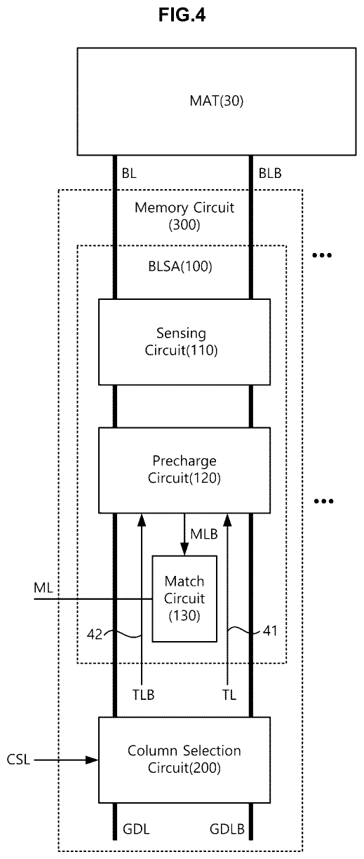

FIG. 4 is a block diagram of a memory device illustrating a memory circuit according to example embodiments of FIG. 3. Referring to FIG. 4, the memory circuit 300 may include a bitline sense amplifier 100 and a column selection circuit 200.

The bitline sense amplifier 100 may include a sensing circuit 110, a precharge circuit 120, and a match circuit 130.

The sensing circuit 110 may detect a voltage change in the bitline signal and amplify both the bitline signal and the complementary bitline signal. For example, a row activation operation may be performed when the bitline BL and the complementary bitline BLB are precharged to a first precharge voltage. In this case, a voltage change may occur in the bitline signal due to data of a memory cell electrically connected to an activated wordline. The sensing circuit 110 may detect the voltage change in the bitline signal and amplify the bitline signal and the complementary bitline signal based on the voltage change that was detected.

The precharge circuit 120 may perform a precharge operation or a comparison operation based on the first and second input signals TL and TLB input through the first and second input lines 41 and 42, respectively.

For example, the precharge circuit 120 may precharge the bitline BL and the complementary bitline BLB to the first precharge voltage during the precharge operation, and the first and second input signals TL and TLB may have the same level or the same voltage. Also, the precharge circuit 120 may generate a matching signal MLB during the comparison operation based on the first and second input signals TL and TLB, and the first and second input signals TL and TLB may have levels or voltages, where the first and second voltages are complementary to one another.

For example, the row activation operation may cause an amplified bitline signal and an amplified complementary bitline signal to be applied to the bitline BL and the complementary bitline BLB, respectively. When the complementary first and second input signals TL and TLB are input, the precharge circuit 120 may compare a first bit value corresponding to the amplified bitline signal with a second bit value corresponding to the first input signal TL and generate a matching signal MLB indicating whether the first and second bit values match. For example, when the first bit value and the second bit value match, the precharge circuit 120 may generate a matching signal MLB of a first level or a first voltage. When the first bit value and the second bit value do not match, the precharge circuit 120 may generate a matching signal MLB of a second level or a second voltage.

The match circuit 130 may control whether a voltage on a match line ML is pulled down according to the matching signal MLB. For example, the match line ML may be precharged to a second precharge voltage before the matching signal MLB is generated. When the matching signal MLB of the first level or the first voltage is applied, the match circuit 130 may maintain the voltage on the match line ML precharged to the second precharge voltage. When the matching signal MLB of the second level or the second voltage is applied, the match circuit 130 may be configured to pull down the voltage on the match line ML, precharged to the second precharge voltage, to a ground voltage.

The column selection circuit 200 may apply the amplified bitline signal and the amplified complementary bitline signal to the global data line GDL and the complementary global data line GDLB, respectively, according to the column select signal CSL. The signals, respectively applied to the global data line GDL and the complementary global data line GDLB, may be transmitted to a global dataline sense amplifier SA.

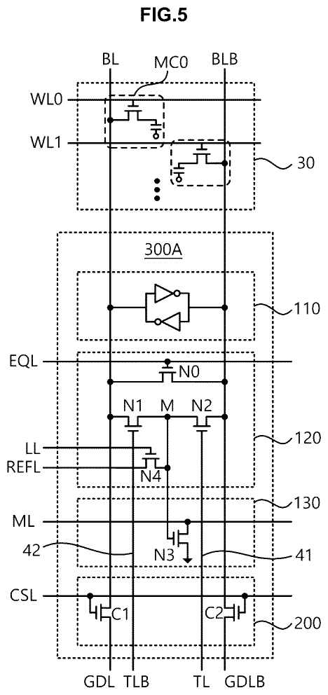

FIG. 5 is a circuit diagram illustrating an example of the memory circuit of FIG. 3. A memory circuit 300A of FIG. 5 may be an example of the memory circuit 300 of FIGS. 3 and 4, but example embodiments are not limited thereto. For example, the memory circuit 300A may be a column circuit including various circuits electrically connected to a bitline BL and a complementary bitline BLB.

Referring to FIG. 5, a memory circuit 300A may include a sensing circuit 110, a precharge circuit 120, a match circuit 130, and a column selection circuit 200. The sensing circuit 110, the precharge circuit 120, and the match circuit 130 may constitute a bitline sense amplifier 100 described above in FIGS. 3 and 4, but example embodiments are not limited thereto.

The sensing circuit 110 may detect a voltage change in a bitline signal during a row activation operation and amplify both the bitline signal and a complementary bitline signal based on the detected voltage change.

The precharge circuit 120 may include a first transistor NO electrically connected between a bitline BL and a complementary bitline BLB and configured to be controlled based on a first control signal EQL, a second transistor N1 electrically connected between the bitline BL and a match node M and configured to be controlled by a second input signal TLB, a third transistor N2 electrically connected between the match node M and the complementary bitline BLB and configured to be controlled by a first input signal TL, and a fourth transistor N4 electrically connected between a reference line REFL and the match node M and configured to be controlled by a second control signal LL.

The match circuit 130 may include a pull-down transistor N3 electrically connected to the match line ML and configured to be controlled by a matching signal MLB output through the match node M.

The column selection circuit 200 may include a sixth transistor C1, electrically connected between the bitline BL and a global data line GDL and configured to be controlled by a column select signal CSL, and a seventh transistor C2 electrically connected between the complementary bitline BLB and a complementary global data line GDLB and configured to be controlled by the column select signal CSL.

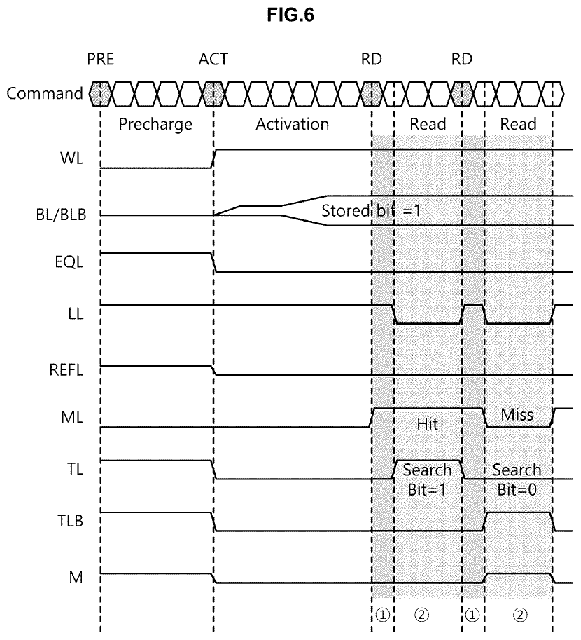

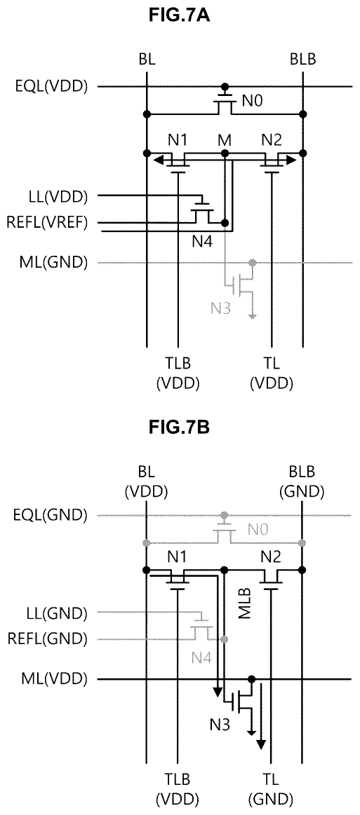

Hereinafter, an operation of the memory circuit 300A of FIG. 5 will be described in detail with reference to FIGS. 6 to 7B. FIG. 6 is a timing diagram illustrating the operation of a memory circuit according to example embodiments. FIG. 7A is a circuit diagram illustrating a precharge operation of the memory circuit of FIG. 5. FIG. 7B is a circuit diagram illustrating a comparison operation of the memory circuit of FIG. 5.

According to example embodiments, the memory circuit 300A may perform a precharge operation based on a precharge (PRE) command applied from the processor 2000. Referring to FIGS. 5 to 7A, during the precharge operation, all wordlines may be deactivated and the connection between the memory cells and the bitline BL may be cut off. Also, during the precharge operation, a first voltage of each of the first control signal EQL, the first input signal TL, the second input signal TLB, and the second control signal LL may have a level or a voltage (e.g., VDD) for turning on corresponding transistors N0, N2, N1, and N4, respectively. The bitline BL and the complementary bitline BLB may be precharged to a first precharge voltage VREF. The first precharge voltage VREF may be, for example, VDD/2, but example embodiments are not limited thereto.

For example, when the fourth transistor N4 is turned on, the first precharge voltage VREF applied to a reference line REFL may be applied to a match node M. The first precharge voltage VREF applied to the match node M may be applied to each of the bitline BL and the complementary bitline BLB through the second and third transistors N1 and N2. The bitline BL and the complementary bitline BLB may be electrically connected through the first transistor N0 to ensure a precharge state. According to example embodiments, the voltage on the match line ML may be tied to a ground voltage GND during the precharge operation and the row activation operation to suppress leakage current.

According to example embodiments, the memory circuit 300A may perform a row activation operation based on an activation (ACT) command applied from the processor 2000. Referring to FIGS. 5 and 6, during the row activation operation, a first voltage of each of the first control signal EQL, the first input signal TL, and the second input signal TLB may have a level or a voltage for turning off the corresponding transistors N0, N2, and N1, respectively. Thus, the first, second, and third transistors N0, N1, and N2 may be turned off. Also, when the wordline WL0 is activated during the row activation operation, the memory cell MC0 may be electrically connected to the bitline BL. The sensing circuit 110 may perform sensing and amplification operations on the bitline signal and the complementary bitline signal.

For example, in the case in which a bit value stored in a memory cell MC0 is ‘1’, when a wordline WL0 is activated, a voltage on the bitline BL may be slightly increased by charge sharing between the memory cell MC0 and the bitline BL. The sensing circuit 110 may detect a voltage difference between the bitline BL and the complementary bitline BLB and amplify the voltage difference. As a result, the voltage on the bitline BL may go to VDD, and the voltage on the complementary bitline BLB may go to a ground voltage GND.

The second control signal LL may have a level or a voltage for turning on the fourth transistor N4 during the row activation operation. Thus, the fourth transistor N4 may be maintained in a turned-on state. The ground voltage GND may be applied to the reference line REFL during the row activation operation. The ground voltage GND applied to the reference line REFL may be applied to the match node M through the fourth transistor N4. Thus, a voltage at the match node M may go to the ground voltage GND during the row activation operation.

According to example embodiments, the memory circuit 300A may perform a comparison operation based on a read command (RD) applied from the processor 2000. The comparison operation may include a first operation of precharging the match line ML to a second precharge voltage and a second operation of generating a matching signal MLB at the match node M and controlling the voltage on the match line ML based on the matching signal MLB, wherein the match line is precharged to the second precharge voltage.

FIG. 6 is a diagram illustrating both a comparison operation of the memory circuit 300A when a bit value corresponding to the first input signal TL (e.g., a search bit value) is ‘1’ and a comparison operation of the memory circuit 300A when the search bit value is ‘0.’

As can be seen in FIGS. 5 and 6, both cases in which the search bit value is ‘1’ and ‘0’ include a first operation period (1) and a second operation period (2). During the first operation, the match line ML may be precharged to a second precharge voltage (e.g., VDD). The second precharge voltage may be, for example, VDD, but example embodiments are not limited thereto.

During the second operation, a first voltage of each of the first control signal EQL and the second control signal LL may have a level or a voltage for turning off the corresponding transistors N0 and N4, respectively. Also, during the second operation, the first input signal TL and the second input signal TLB may have levels or voltages where the first and second voltages are complementary of one another. For example, when the first input signal TL has a level or a voltage corresponding to a bit value of ‘1’ (for example, VDD), the second input signal TLB may have a level or a voltage corresponding to a bit value of ‘0’ (for example, GND), and when the first input signal TL has a level or a voltage corresponding to a bit value of ‘0’ (e.g., GND), the second input signal TLB may have a level or a voltage corresponding to a bit value of ‘1’ (e.g., VDD).

For example, when the bit value stored in the memory cell MC0 is ‘1,’ the voltage on the bitline BL may go to a level or a voltage corresponding to ‘1’ (e.g., VDD) and the voltage on the complementary bitline BLB may go to a level or a voltage corresponding to ‘0’ (e.g., GND) due to the row activation operation. Then, during the second operation, the first input signal TL corresponding to the bit value of ‘1’ may be input to the precharge circuit 120 through the first input line 41 and the second input signal TLB corresponding to the bit value of ‘0’ may be input to the precharge circuit 120 through the second input line 42. The voltage on the complementary bitline BLB is applied to the match node M through the third transistor N2 turned on by the first input signal TL, so that a matching signal MLB of a first level or a first voltage (e.g., GND) may be generated at the match node M. Then, a pull-down transistor N3 of the match circuit 130 may maintain the voltage on the match line ML precharged to the second precharge voltage during the first operation.

When the bit value stored in the memory cell MC0 is ‘1,’ the voltage on the bitline BL may go to a level or a voltage corresponding to ‘1’ (e.g., VDD) and the voltage on the complementary bitline BLB may go to a level or a voltage corresponding to ‘0’ (e.g., GND) due to the row activation operation. Then, during the second operation, the first input signal TL corresponding to the bit value of ‘0’ may be input to the precharge circuit 120 through the first input line 41 and a second input signal TLB corresponding to the bit value of ‘1’ may be input to the precharge circuit 120 through the second input line 42. FIG. 7B illustrates an example embodiment of the comparison operation of a memory circuit 300A. The voltage of the bitline BL is applied to the match node M through the second transistor N1 turned on by the second input signal TLB, so that a matching signal MLB of a second level or a second voltage (e.g., VDD) may be generated at the match node M. Then, a pull-down transistor N3 of the match circuit 130 may be configured to pull down the voltage on the match line ML, precharged to the second precharge voltage, to the ground voltage.

When the bit value stored in the memory cell MC0 is ‘0,’ the voltage on the bitline BL may go to a level or a voltage corresponding to ‘0’ (e.g., GND) and the voltage on the complementary bitline BLB may go to a level or a voltage corresponding to ‘1’ (e.g., VDD) due to the row activation operation. Then, during the second operation, the first input signal TL corresponding to the bit value of ‘1’ may be input to the precharge circuit 120 through the first input line 41 and the second input signal TLB corresponding to the bit value of ‘0’ may be input to the precharge circuit 120 through the second input line 42. The voltage on the complementary bitline BLB is applied to the match node M through the third transistor N2 turned on by the first input signal TL, so that a matching signal MLB of a second level or a second voltage (e.g., VDD) may be generated at the match node M. Then, the pull-down transistor N3 of the match circuit 130 may be configured to pull down the voltage on the match line ML, precharged to the second precharge voltage, to the ground voltage.

When the bit value stored in the memory cell MC0 is ‘0,’ the voltage on the bitline BL may go to a level or a voltage corresponding to ‘0’ (e.g., GND) and the voltage on the complementary bitline BLB may go to a level or a voltage corresponding to ‘1’ (e.g., VDD) due to the row activation operation. Then, during the second operation, the first input signal TL corresponding to the bit value of ‘0’ may be input to the precharge circuit 120 through the first input line 41 and the second input signal TLB corresponding to the bit value of ‘1’ may be input to the precharge circuit 120 through the second input line 42. The voltage on the bitline BL is applied to the match node M through the second transistor N1 turned on by the second input signal TLB, so that a matching signal MLB of a first level or a first voltage (e.g., GND) may be generated at the match node M. Then, the pull-down transistor N3 of the match circuit 130 may maintain the voltage on the match line ML precharged to the second precharge voltage.

According to example embodiments, the memory circuit 300A may perform a normal read operation based on a read command (RD) applied from the processor 2000. Referring to FIG. 5, during the normal read operation, the column select signal CSL may have a level or a voltage for turning on the sixth transistor C1 and the seventh transistor C2. The bitline signal and the complementary bitline signal amplified through the row activation operation may be applied to the global data line GDL and the complementary global data line GDLB through the normal read operation, respectively.

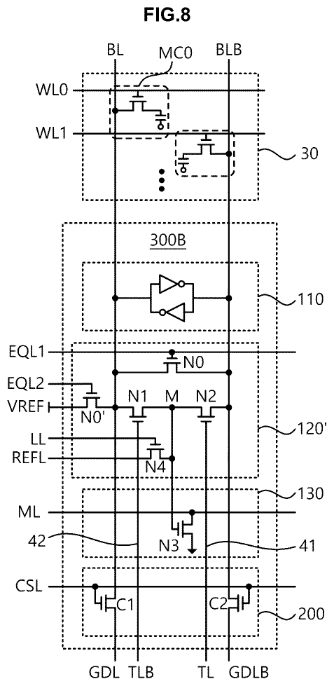

FIG. 8 is a circuit diagram illustrating an example of the memory circuit according to example embodiments. Referring to FIG. 8, a memory circuit 300B is the same as the memory circuit 300A of FIG. 5, except that a precharge circuit 120′ further includes a fifth transistor N0′. Referring to FIG. 8, the first control signal EQL1 may correspond to the first control signal EQL of FIGS. 5, 6, 7A, 7B, 9A, and 10.

The fifth transistor N0′ may be electrically connected between a precharge voltage line, to which a first precharge voltage VREF is applied, and a bitline BL and may be controlled by a third control signal EQL2. For example, during a precharge operation, a third control signal EQL2 may have a level or a voltage for turning on the fifth transistor N0′. Thus, the first precharge voltage VREF may be applied to the bitline BL through the fifth transistor N0′ turned on during the precharge operation.

The memory circuit 300B may operate similarly to the above-described memory circuit 300B, except that the fifth transistor N0′ may be additionally used during the precharge operation.

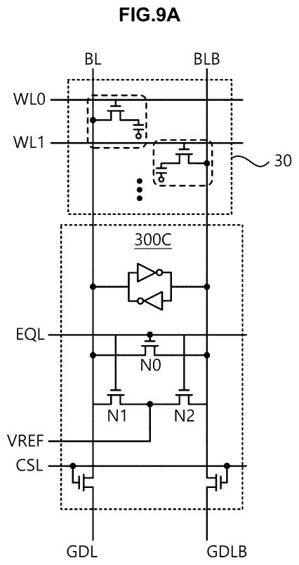

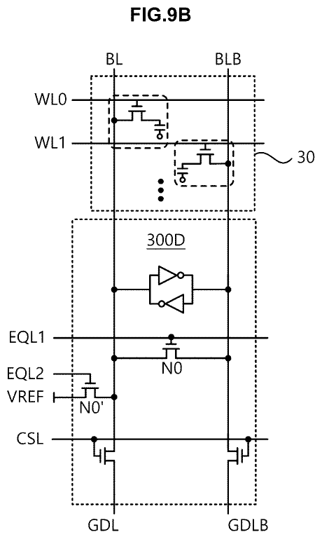

FIG. 9A is a circuit diagram of a memory circuit according to example embodiments. Compared to the memory circuit 300A of FIG. 5, the memory circuit 300C of FIG. 9A does not include the fourth transistor N4 and the pull-down transistor N3. Also, the first and second input signals TL and TLB are not applied through the additional input lines 41 and 42, respectively.

Thus, the memory circuit 300C is unable to perform the above-described comparison operation. However, the memory circuit 300C may perform typical operations of a column circuit (or a bitline sense amplifier), including a precharge operation, a row activation operation, and a normal read operation.

According to example embodiments, a memory circuit for additionally performing a comparison operation as in the memory device 300A of FIG. 5 may be implemented by adding two transistors N4 and N3 to the memory circuit 300C that may be perform general operations and applying external input signals TL and TLB through additional input lines 41 and 42.

FIG. 9B is a circuit diagram of a memory device according to example embodiments. Compared to the memory circuit 300B of FIG. 8, the memory circuit 300D of FIG. 9B does not include the second, third, and fourth transistors N1, N2, and N4 and the pull-down transistor N3. Further, the first and second input signals TL and TLB are not applied through the additional input lines 41 and 42. Referring to FIG. 9B, the first control signal EQL1 may correspond to the first control signal EQL of FIGS. 5, 6, 7A, 7B, 9A, and 10.

Therefore, the memory circuit 300D is unable to perform the above-described comparison operation. However, the memory circuit 300D may perform operations of a general column circuit (or bitline sense amplifier), including a precharge operation, a row activation operation, and a normal read operation.

According to example embodiments, a memory circuit for additionally performing a comparison operation as in the memory device 300B of FIG. 8 may be implemented by adding four transistors N1, N2, N3, and N4 to a memory circuit 300D that may perform general operations and apply external input signals TL and TLB through additional input lines 41 and 42, respectively.

According to the above-described example embodiments, a memory circuit may be implemented which is equipped with a comparison function between data stored in a memory cell and external input data while significantly reducing an overhead.

According to example embodiments, memory circuits 300C and 300D of FIGS. 5 and 8 may be used in conjunction with memory array tiles (MATs) storing metadata that requires a comparison operation (e.g., tags of a cache block). Also, the memory circuits 300C and 300D of FIGS. 9A and 9B may be used in conjunction with MATs storing data that does not require a comparison operation (e.g., data of a cache block).

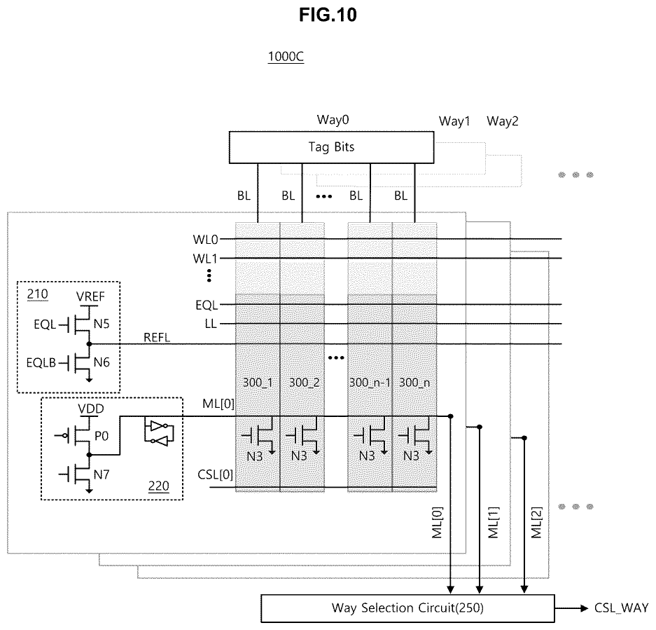

FIG. 10 is a diagram illustrating the operation of a memory device according to example embodiments. A memory device 1000C of FIG. 10 may be an example of the memory devices 1000, 1000A, and 1000B of FIGS. 1 to 3, but example embodiments are not limited thereto.

According to example embodiments, a plurality of memory cells included in a bank of a memory cell array 1100 may include first memory cells that are electrically connected to the same wordline and store tag bits included in tag data, which is an identification value of the cache block. Referring to FIG. 10, for example, memory cells electrically connected to a wordline WL0 and each storing tag bits may be first memory cells. When tag data includes n tag bits, tag bits may be stored in n first memory cells, respectively.

Referring to FIG. 10, the n first memory cells may be electrically connected to the memory circuits 300_1 to 300_n through a bitline BL. Each of the memory circuits 300_1 to 300_n may be either the memory circuit 300A or the memory circuit 300B described above. A complementary bitline BLB is not illustrated for brevity of drawing.

Each of the memory circuits 300_1 to 300_n may precharge the bitline BL and the complementary bitline BLB to the first precharge voltage during a precharge operation. To this end, the memory device 1000C may include a first precharge driver 210 applying a first precharge voltage VREF to a reference line REFL. The first precharge driver 210 may be a component of a peripheral circuit 1200.

Each of the memory circuits 300_1 to 300_n may sense and amplify a bitline signal on the bitline BL during a row activation operation, which has been described previously.

Each of the memory circuits 300_1 to 300_n may perform a comparison operation. For example, first input signals TL, respectively corresponding to tag bits included in tag data of a search-requested cache block, may be input to the memory circuits 300_1 to 300_n during the comparison operation, respectively. A second input signal TLB, input to each of the memory circuits 300_1 to 300_n, may have a level or a voltage that is complementary to a level or a voltage of a corresponding first input signal TL. To this end, the memory device 1000C may include an input driver (not illustrated) applying the first and second input signals TL and TLB to the memory circuits 300_1 to 300_n. The input driver may be a component of the peripheral circuit 1200.

Each of the memory circuits 300_1 to 300_n may generate a matching signal MLB indicating whether a first bit value corresponding to an amplified bitline signal matches a second bit value corresponding to the first input signal TL. The first bit value may be a bit value of a tag bit stored in each of the first memory cells, and the second bit value may be a bit value of a tag bit corresponding to each of the first input signals TL. Each of the memory circuits 300_1 to 300_n may generate a matching signal of a first level or a first voltage when the first bit value and the second bit value match, and may generate a matching signal of a second level or a second voltage when the first bit value and the second bit value do not match.

Referring to FIG. 10, a match line ML may be commonly connected (e.g., electrically connected) to each of n pull-down transistors N3 included in the memory circuits 300_1 to 300_n corresponding to the n first memory cells. Therefore, according to example embodiments, the voltage of the match line ML may be precharged to a second precharge voltage (e.g., VDD) at once during a comparison operation (e.g., during the above-described first operation). To this end, the memory device 1000C may include a second precharge driver 220 applying the second precharge voltage VDD to the match line ML. The second precharge driver 220 may be a component of the peripheral circuit 1200. A voltage on the match line ML, precharged to the second precharge voltage, may be maintained at the second precharge voltage when all matching signals MLB generated by the memory circuits 300_1 to 300_n have a first level or a first voltage, and may be pulled down to a ground voltage when at least one of the matching signals MLB generated by the memory circuits 300_1 to 300_n has a second level or a second voltage.

The memory device 1000C may include a way selection circuit 250 outputting a way select signal CSL_WAY for selecting a cache block corresponding to tag data stored in the first memory cells based on the voltage on the match line ML being maintained at the second precharge voltage.

For example, when tag bits included in the tag data of the search-requested cache block match tag bits stored in the first memory cells, all of the matching signals MLB generated by the memory circuits 300_1 to 300_n may have the first level or the first voltage. A voltage on a match line ML[0] may be maintained at the second precharge voltage, and the way selection circuit 250 may output a way select signal CSL_WAY corresponding to an address of the first memory cells, for example, ‘Way0.’

In the above description, the configuration and operation related to the first memory cells storing tag bits corresponding to ‘Way0’ have been described as an example, but example embodiments are not limited thereto. For example, memory cells corresponding to other ways, such as ‘Way1’ or ‘Way2,’ may also have a similar configuration and operate in a similar manner.

According to example embodiments, a single set may include a plurality of ways. The single set may be stored in the same wordline and a determination may be made, simultaneously in parallel, as to whether search-requested tag data matches the respective ways of the plurality of ways included in the single set. For example, the first and second input signals TL and TLB corresponding to the search-requested tag data may be input in parallel to memory circuits, respectively corresponding to the plurality of ways, by an input driver, not illustrated.

According to example embodiments, a plurality of ways included in a single set may be divided and stored in a plurality of wordlines that may be simultaneously activated. Even in this case, search-requested tag data may be input in parallel to memory circuits, respectively corresponding to the plurality of ways. Thus, a determination may be made, simultaneously in parallel, as to whether the search-requested tag data matches the respective ways of the plurality of ways included in the single set.

According to the above-described example embodiments, a memory device, a sense amplifier, and a memory circuit, capable of comparing data stored in a memory cell and external input data determining whether the stored data and the external input data match without a large overhead, may be provided.

According to example embodiments, a memory device, a sense amplifier, and a memory circuit, capable of determining whether data stored in a memory cell matches external input data, may be provided.

While example embodiments have been illustrated and described above, it will be apparent to those skilled in the art that modifications and variations could be made without departing from the scope of the present inventive concept as defined by the appended claims.

What is claimed is:

1. A memory device comprising:
a plurality of memory cells; and
a plurality of sense amplifiers electrically connected to one or more of the plurality of memory cells, wherein each of the plurality of sense amplifiers are configured to sense and amplify a bitline signal of a bitline to produce an amplified bitline signal,
wherein at least one of the plurality of sense amplifiers is configured to perform operations comprising:
generating a matching signal, indicating whether a first bit value corresponding to the amplified bitline signal and a second bit value corresponding to a first input signal match, based on first and second input signals that are input through first and second input lines, respectively, wherein the first input signal and the second input signal are complementary to one another; and
controlling a voltage on a match line, based on the matching signal.

2. The memory device of claim 1, wherein the at least one of the plurality of sense amplifiers comprises:
a sensing circuit configured to detect a voltage change of the bitline signal and amplify both the bitline signal and a complementary bitline signal of a complementary bitline based on the voltage change that was detected, during a row activation operation;
a precharge circuit configured to precharge the bitline and the complementary bitline to a first precharge voltage during a precharge operation and generate the matching signal based on the first and second input signals during a comparison operation; and
a match circuit configured to control the voltage on the match line according to the matching signal.

3. The memory device of claim 2,
wherein the precharge circuit comprises:
a first transistor electrically connected between the bitline and the complementary bitline and configured to be controlled based on a first control signal;
a second transistor electrically connected between the bitline and a match node and configured to be controlled by the second input signal;
a third transistor electrically connected between the match node and the complementary bitline and configured to be controlled by the first input signal; and
a fourth transistor electrically connected between a reference line and the match node and configured to be controlled by a second control signal, and
wherein the match circuit comprises:
a pull-down transistor electrically connected to the match line and configured to be controlled by the matching signal at the match node.

4. The memory device of claim 3, wherein a first voltage of each of the first control signal, the first input signal, the second input signal, and the second control signal turns on a corresponding transistor during the precharge operation, and
wherein the first precharge voltage is applied to the reference line during the precharge operation and is transferred to the bitline and to the complementary bitline by the fourth transistor, the second transistor, and the third transistor.

5. The memory device of claim 3, wherein a first voltage of each of the first control signal, the first input signal, and the second input signal turns off a corresponding transistor during the row activation operation,
wherein a second voltage of the second control signal turns on the fourth transistor during the row activation operation, and
wherein, when a ground voltage is applied to the reference line during the row activation operation, the ground voltage is also applied to the match node.

6. The memory device of claim 3, wherein the comparison operation comprises:
a first operation configured to precharge the match line to a second precharge voltage, and
a second operation configured to generate the matching signal and configured to control the voltage on the match line based on the matching signal, wherein the match line is precharged to the second precharge voltage.

7. The memory device of claim 6, wherein a first voltage of each of the first control signal and the second control signal turns off a corresponding transistor during the second operation, and
wherein the first input signal and the second input signal have first and second voltages during the second operation, wherein the first and second voltages are complementary to one another.

8. The memory device of claim 3, wherein the pull-down transistor is configured to perform operations comprising:
controlling the voltage on the match line when the matching signal of a first voltage is generated, wherein the first voltage is generated when the first bit value and the second bit value match; and
controlling the voltage on the match line when the matching signal of a second voltage is generated, wherein the second voltage is generated when the first bit value and the second bit value do not match.

9. The memory device of claim 8, wherein the matching signal has the second voltage when the first bit value is 1 and the second bit value is 0,
wherein the matching signal has the second voltage when the first bit value is 0 and the second bit value is 1,
wherein the matching signal has the first voltage when the first bit value is 0 and the second bit value is 0, and
wherein the matching signal has the first voltage when the first bit value is 1 and the second bit value is 1.

10. The memory device of claim 3, wherein the precharge circuit further comprises:
a fifth transistor configured to be controlled by a third control signal and electrically connected between a precharge voltage line to which the first precharge voltage is applied, and the bitline.

11. The memory device of claim 3, further comprising:
a column selection circuit configured to transfer the amplified bitline signal and the complementary bitline signal that was amplified to a global data line and a complementary global data line, respectively,
wherein the column selection circuit comprises:
a sixth transistor electrically connected between the bitline and the global data line, wherein the sixth transistor is configured to be controlled by a column select signal; and
a seventh transistor electrically connected between the complementary bitline and the complementary global data line, wherein the seventh transistor is configured to be controlled by the column select signal.

12. The memory device of claim 11, wherein a first voltage of the column select signal turns on the sixth transistor and the seventh transistor during a normal read operation.

13. The memory device of claim 1, wherein each of the plurality of memory cells comprises one of a dynamic random access memory (DRAM) cell, a static random access memory (SRAM) cell, or a magnetic random access memory (MRAM) cell.

14. The memory device of claim 1, wherein the plurality of memory cells comprises a plurality of first memory cells electrically connected to a same wordline and each of the plurality of first memory cells is configured to store a tag bit of a plurality of tag bits from tag data, wherein the tag data comprises an identification value of a cache block, and
wherein the at least one of the plurality of sense amplifiers comprises a plurality of first sense amplifiers, respectively corresponding to the plurality of first memory cells, and
wherein first input signals that are input to the plurality of first sense amplifiers correspond to the plurality of tag bits from the tag data of a search-requested cache block, respectively, and
wherein the first input signals comprises the first input signal.

15. The memory device of claim 14, wherein the first bit value comprises a first tag bit stored in a respective first memory cell of the plurality of first memory cells,
wherein the second bit value comprises a second tag bit corresponding to a respective first input signal of the first input signals, and
wherein each of the plurality of first sense amplifiers is configured to generate the matching signal of a first voltage when the first bit value and the second bit value match, and is configured to generate the matching signal of a second voltage when the first bit value and the second bit value do not match.

16. The memory device of claim 15, wherein each of the plurality of first sense amplifiers comprises:
a pull-down transistor electrically connected to the match line and configured to control the voltage on the match line based on the matching signal, and
wherein the match line is configured to be precharged to a second precharge voltage,
wherein the pull-down transistor is configured to maintain the second precharge voltage on the match line when respective matching signals of the plurality of first sense amplifiers have the first voltage, and is configured to transfer a ground voltage to the match line when at least one of the respective matching signals of the plurality of first sense amplifiers has the second voltage.

17. The memory device of claim 16, further comprising a way selection circuit configured to output a way selection signal for selecting the cache block corresponding to the tag data stored in the plurality of first memory cells, based on the match line being maintained at the second precharge voltage.

18. The memory device of claim 17, wherein the plurality of memory cells comprises a plurality of second memory cells configured to store data of the cache block corresponding to the tag data stored in the plurality of first memory cells, and
wherein the data stored in the plurality of second memory cells is output to an exterior of the memory device based on a way select signal of the way selection circuit.

19. A sense amplifier electrically connected to a bitline and a complementary bitline, the sense amplifier comprising:
a sensing circuit configured to detect a voltage change of a bitline signal and amplify the voltage change that was detected based on the bitline signal and a complementary bitline signal to produce an amplified bitline signal;
a precharge circuit configured to precharge the bitline and the complementary bitline to a precharge voltage; and
a pull-down transistor electrically connected to a match line,
wherein the precharge circuit is configured to generate a matching signal indicating whether a first bit value corresponding to the amplified bitline signal matches a second bit value corresponding to a first input signal, based on the first input signal and a second input signal that are input through first and second input lines, respectively,
wherein the first input signal and the second input signal are complementary to one another, and
wherein the pull-down transistor is configured to control a voltage on the match line, based on the matching signal.

20. A memory circuit electrically connected to a bitline and a complementary bitline where the memory circuit is configured to perform a precharge operation on the bitline and the complementary bitline, the memory circuit comprising:
a first transistor electrically connected between the bitline and the complementary bitline;
a second transistor electrically connected between the bitline and a match node and configured to be controlled by a second input signal;
a third transistor electrically connected between the match node and the complementary bitline and configured to be controlled by a first input signal; and
a fourth transistor configured to transfer a precharge voltage to the match node,
wherein the bitline and the complementary bitline are configured to be precharged to the precharge voltage while the first transistor, the second transistor, the third transistor, and the fourth transistor are turned on,
wherein the match node has a first voltage indicating whether a first bit value corresponding to a bitline signal matches a second bit value corresponding to the first input signal, in response to the first transistor and the fourth transistor being turned off and the first and second input signals being input through the second transistor and the third transistor, respectively, and
wherein the first and second input signals are complementary to one another.
